(19) United States
(12) Patent Application Publication
(10) Pub. No.: US 2006/0014327 A1
(43) Pub. Date: Jan. 19, 2006

(54) Method of fabricating PCB including embedded passive chip

(75) Inventors: Suk-Hyeon Cho, Daejeon (KR); Seok-Kyu Lee, Chungcheongbuk-do (KR); Jong-Kuk Hong, Chungcheongnam-do (KR); Ho-Sik Jun, Chungcheongbuk-do (KR); Jin-Soo Jeong, Seoul (KR); Chang-Sup Ryu, Daejeon (KR); Jin-Yong Ahn, Daejeon (KR)

Correspondence Address: GOTTLIEB RACKMAN & REISMAN PC, 270 MADISON AVENUE, 8TH FLOOR, NEW YORK, NY, 100160601, US

(73) Assignee: SAMSUNG ELECTRO-MECHANICS CO., LTD.

(21) Appl. No.: 10/976,732

(22) Filed: Oct. 29, 2004

(30) Foreign Application Priority Data
Jul. 14, 2004 (KR) 2004-54820

(51) Int. Cl. H01L 21/50

(52) U.S. Cl. 438/125

(57) ABSTRACT

Disclosed is a method of fabricating a PCB including an embedded passive chip, in which the passive chip is mounted on the PCB and an insulator is then laminated on the PCB, or in which a blind hole for receiving the passive chip is formed in the PCB and the passive chip is mounted in the blind hole.

### BACKGROUND OF THE INVENTION

1. Field of the Invention

The present invention relates, in general, to a method of fabricating a printed circuit board (PCB) PCB including an embedded passive chip and, more particularly, to a method of fabricating a PCB including an embedded passive chip, in which a blind hole for receiving the passive chip is formed on the PCB and the passive chip is mounted in the blind hole, or in which the passive chip is mounted on the PCB and an insulator is laminated on the PCB.

2. Description of the Prior Art

Typical discrete chip resistors or discrete chip capacitors have been frequently mounted on most printed circuit boards (PCB), but, recently, PCBs are developing in which passive components, such as resistors or capacitors, are embedded.

A technology regarding the PCBs, including the passive components embedded therein, achieves substitution of conventional chip resistors or chip capacitors by mounting the passive components, such as the resistors or capacitors, on an external surface of a PCB or in an internal layer of the PCB according to a novel process employing a novel material (substance).

In other words, the PCB including the passive component embedded therein has a structure in which the passive component, for example, the capacitor, is embedded in the internal layer of the PCB or mounted on the external surface of the PCB, and if the capacitor as the passive component is integrated with the PCB to act as one part of the PCB regardless of a size of a substrate, the capacitor is called an “embedded capacitor” and the resulting PCB is called an “embedded capacitor PCB”.

One of the most important features of the PCB including the passive component embedded therein is that since the passive component is already mounted as the part of the PCB in the PCB, it is not necessary to mount the passive component on a surface of the PCB.

On the whole, a technology of fabricating the PCB including the passive component embedded therein may be classified into three methods, and a description will be given of the three methods.

Firstly, there is a method of fabricating a polymer thick film type of capacitor, in which coating of a polymer capacitor paste and thermal hardening, that is drying, are conducted to fabricate a capacitor.

In the above method, after the polymer capacitor paste is coated on an internal layer of a PCB and dried, a copper paste is printed on the resulting PCB and dried so that electrodes are formed, thereby making an embedded capacitor.

A second method is to coat a ceramic filled photosensitive resin on a PCB to fabricate an embedded discrete type of capacitor, and Motorola Inc. in USA holds a patent for related technologies.

In detail, the photosensitive resin containing ceramic powder is coated on the PCB, a copper foil is laminated on the resulting PCB to form upper and lower electrodes, a circuit pattern is formed, and the photosensitive resin is etched to fabricate the discrete type of capacitor.

A third method is to insert an additional dielectric layer having a capacitance characteristic in an internal layer of a PCB so as to substitute for a decoupling capacitor conventionally mounted on a surface of a PCB, thereby fabricating a capacitor, and Sanmina Corp. in USA holds a patent for related technologies.

According to the third method, the dielectric layer including a power supply electrode and a grounded electrode is inserted into the internal layer of the PCB to fabricate a power distribution type of decoupling capacitor.

However, the above conventional methods are problematic in that practicality is reduced because of very low capacitance. To avoid the above problem, an effort has been made to employ a material having high capacitance and to reduce an interval between contact parts, thereby increasing the capacitance.

However, there is a difficulty in reducing the interval through the conventional methods regarding the PCB, and since material having high capacitance is very brittle, it is problematic to employ material having the high capacitance in the course of fabricating the PCB.

To avoid the above problems, in recent years, an effort has been made to embed a capacitor chip, which was conventionally mounted on a surface of the PCB, in the PCB. With respect to this, Japanese Pat. Application No. 2002-118367A, which is submitted by IBIDEN Co. Ltd. in Japan, already discloses a method of embedding a capacitor chip into a core layer of a PCB.

In the above patent, the capacitor chip is embedded in the core layer in such a way that after the capacitor chip is inserted into the core, semi-hardened epoxy resin is coated on the resulting core, heated and pressurized. The resulting structure is drilled using a laser drill, and an electric connection is achieved by plating.

However, the method is problematic in that since the capacitor chip is mounted in the core, the capacitor chip becomes more distant from an IC mounted on a surface of the core. Additionally, since after a through hole is formed through the core, the capacitor chip is mounted in the core, it is required to conduct an additional process for forming the hole, and circuits are not formed on upper and lower sides of the capacitor chip even though the capacitor chip is mounted in the through hole.

Furthermore, in the course of mounting the capacitor chip in the through hole of the core, it is not easy to handle because the capacitor chip may fall down from the core.

### SUMMARY OF THE INVENTION

Therefore, the present invention has been made keeping in mind the above disadvantages occurring in the prior arts, and an object of the present invention is to provide a method of fabricating a PCB including an embedded passive chip, in which a blind hole is formed in an insulator while a copper foil constitutes a bottom side of the blind hole or while the copper foil is removed from the blind hole so that the passive chip does not fall down from the blind hole after it is mounted in the blind hole.

Another object of the present invention is to provide a method of fabricating a PCB including an embedded passive chip, in which a blind hole is formed in a core in such a way that a copper foil constitutes a bottom side of the blind hole, so that it is possible to form a circuit on the copper foil acting as the bottom side and a capacitor chip does not fall down from the blind hole after the passive chip is mounted in the blind hole.

A further object of the present invention is to provide a method of fabricating a PCB including an embedded capacitor chip, in which after a passive chip is mounted on surfaces of an insulator or a core layer, an insulating resin layer is laminated on the resulting layer to simplify a process of forming a blind hole and to reduce a distance between an IC chip and the passive chip, thereby improving electric properties. At this time, a hole is formed through the unhardened insulating resin layer to easily embed the passive chip in the insulator.

Yet another object of the present invention is to provide a method of fabricating a PCB including an embedded passive chip, in which after a material having electric conductivity is coated on an electrode of a passive chip, the electrode is mounted in a blind hole so that electricity can flow to a pad at a bottom of the blind hole or a pad on a surface of an internal layer of the PCB in a heating and pressurizing process, or in which after the material having electric conductivity is coated on the pad at the bottom of the blind hole or the pad on the surface of the internal layer of the PCB, the passive chip is mounted in the blind hole to achieve electric connection in the heating and pressurizing process, thereby reducing the number of holes required to form contact parts, and significantly reducing production expenses and time.

Still another object of the present invention is to provide a method of fabricating a PCB including an embedded passive chip, in which after the passive chip is mounted in a blind hole or mounted on a surface of an insulating layer or a core layer, a bump having electric conductivity is formed on an upper conductive layer before an insulating resin is coated on the resulting layer and a heating and pressurizing process is conducted, and the covering of the insulating resin layer and the heating and pressurizing process are carried out to achieve an electric connection, thereby simplifying a process of forming the hole required to achieve the electric connection after the heating and pressurizing process, and effectively achieving the electric connection of a passive component.

The above objects can be accomplished by providing a method of fabricating a PCB including an embedded passive chip, which comprises a first step of forming a blind hole, in which the passive chip is to be mounted, in a first raw material layer laminated on a substrate constituting a core layer; a second step of mounting the passive chip in the blind hole after a first circuit pattern is formed on a first copper foil of the first raw material layer, laminating an insulator or a second raw material layer, which consists of the insulator and a second copper foil formed on one side of the insulator, on the first raw material layer, in which the passive chip is mounted, and heating and pressurizing the resulting substrate; a third step of forming a via hole electrically connecting an electrode of the passive chip to an external part therethrough; and a fourth step of forming a copper clad on the via hole and a second circuit pattern on the external part.

Furthermore, the present invention provides a method of fabricating a PCB including an embedded passive chip, which comprises a first step of forming a blind hole, in which the passive chip is to be mounted, in a core layer in such a way that a portion of a first copper foil constitutes a bottom side of the blind hole so that a first circuit pattern is formed on the first copper foil; a second step of mounting the capacitor chip in the blind hole, laminating a first insulator or a first raw material layer, which consists of the first insulator and a second copper foil formed on one side of the first insulator, on one side of the core layer, in which the capacitor chip is mounted, and heating and pressurizing the resulting core layer; a third step of forming a second circuit pattern on the first copper foil constituting the bottom side of the blind hole, laminating a second insulator or a second raw material layer, which consists of the second insulator and a third copper foil formed on one side of the second insulator, on the bottom side of the blind hole, on which the second circuit pattern is formed, and heating and pressurizing the resulting second raw material layer; a fourth step of forming a via hole electrically connecting an electrode of the capacitor chip to an external part; and a fifth step of forming a copper clad on the via hole and a third circuit pattern on the external part.

Further, the present invention provides a method of fabricating a PCB including an embedded passive chip, which comprises a first step of mounting the passive chip on an insulator of a raw material layer laminated on a substrate constituting a core layer; a second step of laminating an unhardened insulating resin layer on the raw material layer, on which the passive chip is mounted in the first step, and heating and pressurizing the resulting raw material layer; a third step of forming a via hole electrically connecting an electrode of the passive chip to an external part therethrough; and a fourth step of forming a copper clad on the via hole and a circuit pattern on the external part.

Additionally, the present invention provides a method of fabricating a PCB including an embedded passive chip, which comprises a first step of mounting the passive chip on a core layer, on which a first circuit pattern is formed; a second step of laminating an insulator or a raw material layer, which consists of the insulator and a copper foil formed on one side of the insulator, on both sides of the core layer, and heating and pressurizing the resulting core layer; a third step of forming a via hole electrically connecting an electrode of the passive chip to an external part therethrough; and a fourth step of forming a copper clad on the via hole and a second circuit pattern on the external part.

As well, the present invention provides a method of fabricating a PCB including an embedded passive chip, which comprises a first step of forming a blind hole, in which the passive chip is to be mounted, in a first insulator of a raw material layer laminated on a substrate constituting a core layer, and mounting the passive chip in the blind hole after a first circuit pattern is formed; a second step of laminating a second insulator on the first raw material layer, in which the passive chip is mounted, laminating a copper foil including an electric conductive bump on the second insulator, and heating and pressurizing the resulting structure; and a third step of forming a second circuit pattern on an external part.

Furthermore, the present invention provides a method of fabricating a PCB including an embedded passive chip, which comprises a first step of forming a blind hole, in which the passive chip is to be mounted, in a core layer; a second step of mounting the passive chip in the blind hole after a first circuit pattern is formed on a first copper foil of the first raw material layer; a third step of laminating a second raw material layer, which includes a second copper foil having a conductive bump, on the first raw material layer, in which the passive chip is mounted, and heating and pressurizing the resulting structure; and a fourth step of forming a second circuit pattern on an external part.

Furthermore, the present invention provides a method of fabricating a PCB including an embedded passive chip, which comprises a first step of mounting the passive chip on a core layer, or on a first raw material layer laminated on a substrate constituting the core layer; a second step of laminating a second raw material layer, which includes a copper foil having a conductive bump, on the first raw material layer, in which the passive chip is mounted, and heating and pressurizing the resulting structure; and a third step of forming a circuit pattern on an external part.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1e are sectional views illustrating the fabrication of a PCB including an embedded passive chip according to the first embodiment of the present invention;

FIGS. 2a to 2e are sectional views illustrating the fabrication of a PCB including an embedded passive chip according to the second embodiment of the present invention;

FIGS. 3a to 3d are sectional views illustrating the fabrication of a PCB including an embedded passive chip according to the third embodiment of the present invention;

FIGS. 4a to 4d are sectional views illustrating the fabrication of a PCB including an embedded passive chip according to the fourth embodiment of the present invention;

FIGS. 5a to 5e are sectional views illustrating the fabrication of a PCB including an embedded passive chip according to the fifth embodiment of the present invention;

FIGS. 6a to 6c are sectional views illustrating the fabrication of a PCB including an embedded passive chip according to the sixth embodiment of the present invention;

FIG. 7 illustrates an electric connection between patterns, formed on lower copper foils of blind holes according to the first to sixth embodiments of the present invention, and electric conductive materials; and

FIGS. 8a to 8d illustrate various patterns formed on the lower copper foils used in the first to sixth embodiments of the present invention.

### DETAILED DESCRIPTION OF THE INVENTION

Hereinafter, a detailed description will be given of preferred embodiments according to the present invention, referring to the drawings.

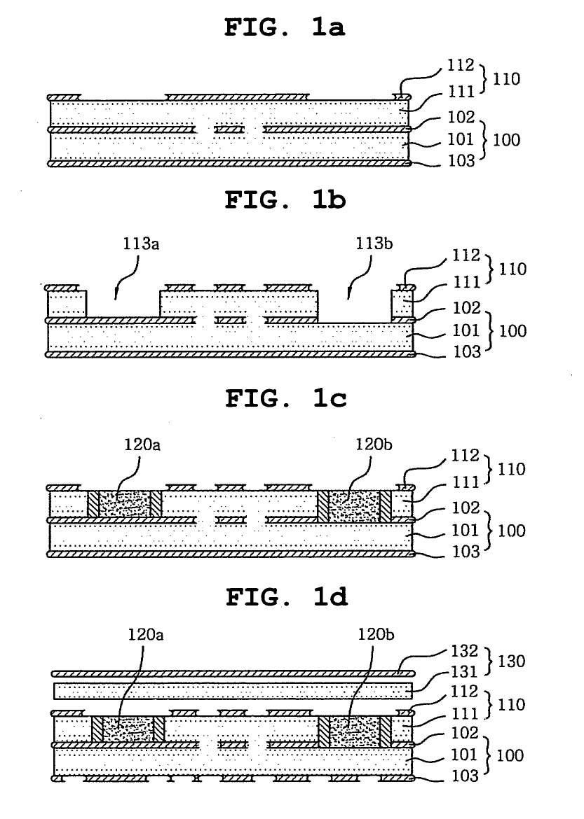

FIGS. 1a to 1e are sectional views illustrating the fabrication of a PCB including an embedded passive chip according to the first embodiment of the present invention.

As shown in FIG. 1a, a circuit pattern is formed on a copper foil 102 of a substrate 100 constituting a core layer according to a photolithography process, and an insulator 111 or a raw material layer 110, which consists of the insulator 111 and a copper foil 112 formed on one side of the insulator 111, is laminated on the substrate 100 in a vacuum by heating and pressurization.

A copper clad laminate used as the substrate 110 may be classified into a glass/epoxy copper clad laminate, a heat-resistant resin copper clad laminate, a paper/phenol copper clad laminate, a high-frequency copper clad laminate, a flexible copper clad laminate, and a composite copper clad laminate according to its application. However, it is preferable to use the glass/epoxy copper clad laminate 100, in which copper foils 102, 103 are plated on an insulating resin layer 101, in the course of fabricating a double-sided printed circuit board and a multilayer printed circuit board.

After a dry film (not shown) is coated on the substrate 110, the dry film is exposed and developed using an art work film, on which a predetermined pattern is printed, to form a predetermined pattern on the dry film, and corrosive liquid is sprayed to remove the remaining portion of the copper foil 102 except a portion of the copper foil 102, which is protected by the dry film, and to strip the used dry film, thereby forming a wiring pattern in the copper foil 102.

The dry film includes three layers, that is, a cover film, a photoresist film, and a Mylar film, and the photoresist film substantially acts as a resist.

The art work film, having the predetermined pattern printed thereon, is attached to the dry film, and then exposed to ultraviolet rays to achieve the exposing and developing processes of the dry film.

At this time, the ultraviolet rays are not transmitted through a black portion of the art work film, on which the pattern is printed, but through a remaining portion of the art work film, on which the pattern is not printed, causing hardening of the dry film below the art work film.

When the copper clad laminate 102, on which the partially hardened dry film is formed, is dipped into a developing solution, a unhardened portion of the dry film is removed by the developing solution, and a hardened portion of the dry film remains to form a resist pattern. Examples of the developing solution include a sodium carbonate (Na₂CO₃) aqueous solution or a potassium carbonate (K₂CO₃) aqueous solution.

As described above, after the resist pattern is formed on the substrate 100 according to the photolithography process, the corrosive liquid is sprayed to remove the remaining portion of the copper foil 102 except a portion of the copper foil 102, which is protected by the resist pattern, and to strip the used resist pattern, thereby forming a wiring pattern in the copper foil 102.

Additionally, as shown in FIG. 1b, blind holes 113a, 113b are formed at locations at which passive chips are to be mounted, and a circuit pattern is formed on a copper foil 112, through which the chips are to be inserted, according to a photolithography process. In this regard, corrosive liquid may be sprayed onto lower parts of the blind holes for receiving the passive chips 120a, 120b to completely remove the lower parts, or the corrosive liquid may be prevented from flowing to the lower parts of the blind holes to allow the pattern of the copper foil 112, formed in the course of forming the circuit pattern, to remain.

Subsequently, as shown in FIG. 1c, the passive chips 120a, 120b are mounted in the blind holes 113a, 113b formed in portions, in which the passive chips 120a, 120b are to be mounted.

Successively, as shown in FIG. 1d, an insulator 131 or a substrate 130, which consists of the insulator 131 and a copper foil 132 formed on one side of the insulator 131, is laminated, and heated and pressurized in a vacuum, thereby embedding the passive chips 120a, 120b in the PCB.

Next, as shown in FIG. 1e, via holes 141-146 are formed, and walls of the via holes 141-146 are subjected to electroless copper plating and electrolytic copper plating processes to form copper clads 151-156 so as to connect electrodes of the passive chips 120a, 120b embedded in the PCB to each other through circuits.

In this regard, the via holes 141-146 are preferably formed at predetermined positions using a computer numerical control drill (CNC drill) or a laser beam.

A process employing the CNC drill is useful to form a via hole through a double-sided PCB or to form a through hole through a multilayer PCB.

After the via hole or through hole is formed using the CNC drill, a deburring process is preferably conducted to remove copper foil burrs generated during the drilling process, and dust attached to a wall of the via hole and to the surface of the copper foil. At this time, the surface of the copper foil becomes rough, thus improving an attachment strength of copper to the copper foil in a copper plating process.

A process employing the laser beam is useful to form a micro via hole through the multilayer PCB. For example, the copper foil and the insulating resin layer may be simultaneously holed by a yttrium aluminum garnet (YAG) laser beam, or the insulating resin layer 111 may be holed by a carbon dioxide laser beam after a portion of the copper foil corresponding in position to the via hole is etched.

As well, the insulating resin layer of the substrate may be molten due to heat generated in the course of forming the via hole to form a smear on the wall of the via hole. Accordingly, it is preferable that a desmear process be conducted after the via hole is formed so as to remove the smear from the wall of the via hole.

Meanwhile, the wall of the via hole of the substrate is comprised of the insulating resin layer, and thus, it is impossible to conduct an electrolytic copper. plating process directly after the via hole is formed. Accordingly, an electroless copper plating process is carried out so as to electrically connect the via holes (B) to each other and to achieve an electrolytic copper plating process.

Since the electroless copper plating process is a process of plating an insulator, it is difficult to expect a reaction caused by ions with electricity. The electroless copper plating process is achieved by a deposition reaction, and the deposition reaction is promoted by a catalyst.

The catalyst must be attached to a surface of a material to be plated, so as to separate copper from a plating solution to deposit copper on the material. This means that the electroless copper plating process requires many pre-treating processes.

For example, the electroless copper plating process may include a degreasing step, a soft etching step, a pre-catalyst treating step, a catalyst treating step, an acceleration step, an electroless copper plating step, and an anti-oxidizing step.

In the degreasing step, oxides, impurities, and particularly oils and fats are removed from a surface of the copper foil using a chemical containing acid or alkaline surfactants, and the resulting copper foil is rinsed to completely remove the surfactants therefrom.

The soft etching step makes the surface of the copper foil slightly rough (for example, a roughness of about 1-2 μm) to uniformly deposit copper particles on the copper foil during the plating process, and to remove contaminants which are not removed during the degreasing step, from the copper foil.

In the pre-catalyst treating step, the substrate is dipped in a dilute first catalyst-containing chemical to prevent a second catalyst-containing chemical used in the catalyst treating step from being contaminated or to prevent a concentration of the second catalyst-containing chemical from being changed. Moreover, because the substrate is preliminarily dipped in the first chemical, having the same components as the second chemical, prior to treating the substrate using the second chemical, the treating of the substrate using the catalyst is more preferably achieved. At this time, it is preferable that 1-3% chemical be used in the pre-catalyst treating step.

In the catalyst treating step, catalyst particles are coated on the copper foil and insulating resin layer (for example, the wall of the via hole of the substrate. The catalyst particles may be preferably exemplified by a Pd—Sn compound, and Pd₂⁻ dissociated from the Pd—Sn compound contributes to promotion of the plating of the substrate in conjunction with Cu₂⁺ plated on the substrate.

During the electroless copper plating step, it is preferable that a plating solution contain CuSO₄, HCHO, NaOH, and a stabilizer. It is important to control the composition of the plating solution because chemical reactions constituting the plating process of the substrate 110 must maintain an equilibrium state in order to continuously conduct the plating process. To desirably maintain the composition of the plating solution, it is necessary to properly replenish each component constituting the plating solution, to mechanically agitate the plating solution, and to smoothly operate a cycling system of the plating solution. Furthermore, it is necessary to use a filtering device for removing byproducts resulting from the reaction, and the removal of the byproducts using the filtering device contributes to extension of the life of the plating solution.

An anti-oxidizing layer is coated on the copper clads to prevent oxidation of the copper clads caused by alkaline components remaining after the electroless copper plating step during the anti-oxidizing step.

However, since an electroless copper-plated layer usually has poorer physical properties than an electrolytic copper-plated layer, the electroless copper-plated layer is thinly formed.

Additionally, a dry film (not shown) is coated on the copper foils 103, 132, and exposed and developed using an artwork film, having a predetermined pattern printed thereon, to be patterned. Furthermore, corrosive liquid is sprayed to remove the remaining portion of the copper foils 103, 132 except portions of the copper foils, which are protected by the dry film, and to strip the used dry film, thereby forming wiring patterns in the copper foils 103, 132.

As well, the passive chips, as shown in FIGS. 1a to 1e, may be mounted in two or more layers of insulator as well as in one layer of insulator.

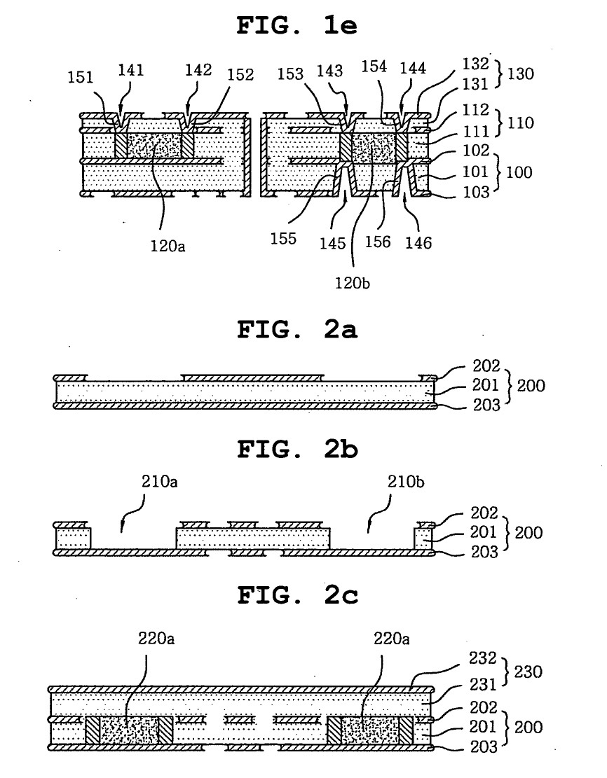

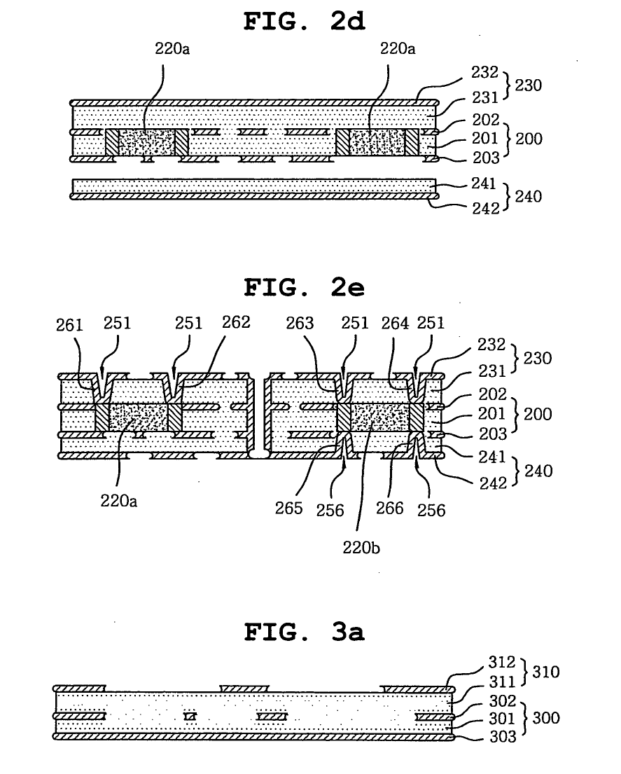

FIGS. 2a to 2e are sectional views illustrating the fabrication of a PCB including an embedded passive chip according to the second embodiment of the present invention.

The second embodiment as shown in FIGS. 2a to 2e is different from the first embodiment as shown in FIGS. 1a to 1e in that since the passive chip is mounted in a core layer, various patterns may be formed on portions of a copper foil, in which passive components are to be mounted, in the second embodiment.

As shown in FIG. 2a, copper foils 202, 203 are coated on an insulating resin layer 201 to prepare a copper clad laminate as a substrate 200, and a portion of the copper foil 202 is removed according to a photolithography process to form blind holes 210a, 210b, in which passive chips 220a, 220b are to be mounted.

Furthermore, as shown in FIG. 2b, the blind holes 210a, 210b, in which the passive chips 220a, 220b are to be mounted, are formed in the substrate 200 in such a way that the copper foil 203 positioned at bottoms of the blind holes 210a, 210b is not removed so that the passive chips 220a, 220b mounted in the blind holes 210a, 210b do not fall from the blind holes.

Subsequently, as shown in FIG. 2c, after the passive chips 220a, 220b are mounted in the blind holes 210a, 210b, an insulator 231 or a raw material layer 230, which consists of the insulator 231 and a copper foil 232 formed on one side of the insulator 231, is laminated on the resulting substrate, and heated and pressurized in a vacuum to embed the passive chips 220a, 220b.

Additionally, as shown in FIG. 2d, a circuit is preferably formed on the copper foil 203 constituting the bottoms of the blind holes 210a, 210b according to a photolithography process, or alternatively, if unnecessary, the copper foil 203 is completely removed. An insulator 241 or a substrate 240, which consists of the insulator 241 and a copper foil 242 formed on one side of the insulator 241, is laminated on the copper foil, and heated and pressurized in a vacuum.

Subsequently, as shown in FIG. 2e, via holes 251-256 are formed, and walls of the via holes 251-256 are subjected to electroless copper plating and electrolytic copper plating processes to form copper clads 261-266 so as to connect electrodes of the passive chips 220a, 220b embedded in the PCB to each other through circuits. Additionally, after a coating of a dry film (not shown), the dry film is exposed and developed using an artwork film having a predetermined pattern printed thereon to be patterned. Furthermore, corrosive liquid is sprayed to remove the remaining portion of the copper foils except portions of the copper foils, which are protected by the dry film, and to strip the used dry film, thereby forming wiring patterns in the copper foils 232, 242.

As well, the passive chips, as shown in FIGS. 2a to 2e, may be mounted in two or more layers of insulator as well as in one layer of insulator.

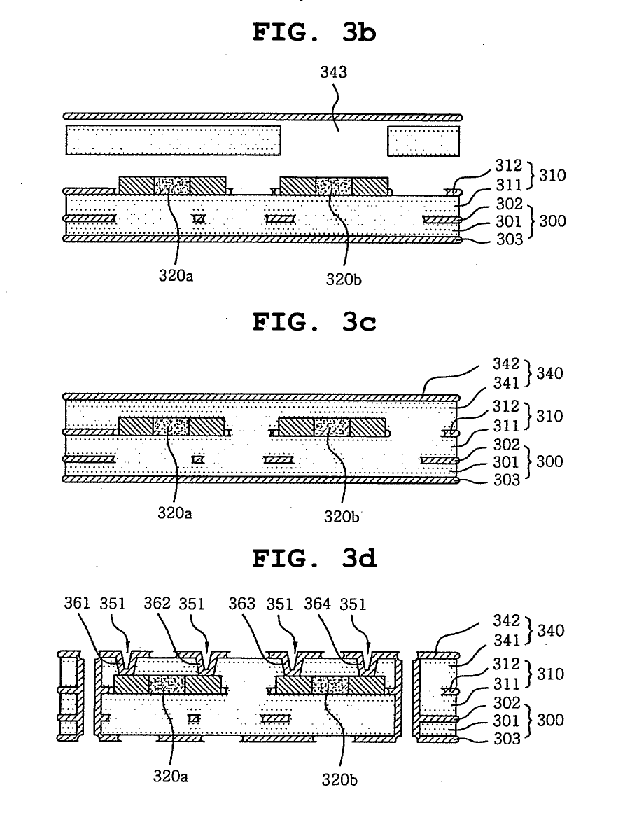

FIGS. 3a to 3d are sectional views illustrating the fabrication of a PCB including an embedded passive chip according to the third embodiment of the present invention.

As shown in FIG. 3a, a circuit pattern is formed on a copper foil 302 of a substrate 300 constituting a core layer according to a photolithography process, and an insulator 311 or a substrate 310, which consists of the insulator 311 and a copper foil 312 formed on one side of the insulator 311, is laminated on the circuit pattern in a vacuum by heating and pressurization. In this regard, it is preferable to remove a portion of the copper foil 312, through which passive chips 320a, 320b are to be mounted, according to a photolithography process.

Subsequently, as shown in FIG. 3b, structures, in which the passive chips 320a, 320b are to be mounted, are formed according to a photolithography process, the passive chips 320a, 320b are mounted in the structures, and an insulator 341 or a substrate 340, which consists of the insulator 341 and a copper foil 342 formed on one side of the insulator 341, is laminated on the chips. At this time, it is preferable that the insulator 341 be holed so as to easily embed the passive chips 320a, 320b in the insulator 341, but holes 343 may not be formed through the insulator 341.

Additionally, as shown in FIG. 3c, after the passive chips 320a, 320b are mounted in the structures, the insulator 341 or the substrate 340, which consists of the insulator 341 and the copper foil 342 formed on one side of the insulator 341, is coated on the chips, and heated and pressurized in a vacuum to embed the passive chips 320a, 320b in the insulator.

Successively, as shown in FIG. 3d, via holes 351-354 are formed, and walls of the via holes 351-354 are subjected to electroless copper plating and electrolytic copper plating processes to form copper clads 361-364 so as to connect electrodes of the passive chips 320a, 320b embedded in the PCB to each other through circuits. Additionally, after a coating of a dry film (not shown), the dry film is exposed and developed using an artwork film, having a predetermined pattern printed thereon, to be patterned. Furthermore, corrosive liquid is sprayed to remove the remaining portion of the copper foils except portions of the copper foils, which are protected by the dry film, and to strip the used dry film, thereby forming wiring patterns in the copper foils 303, 342.

As well, the passive chips, as shown in FIGS. 3a to 3d, may be mounted in two or more layers of insulator as well as in one layer of insulator.

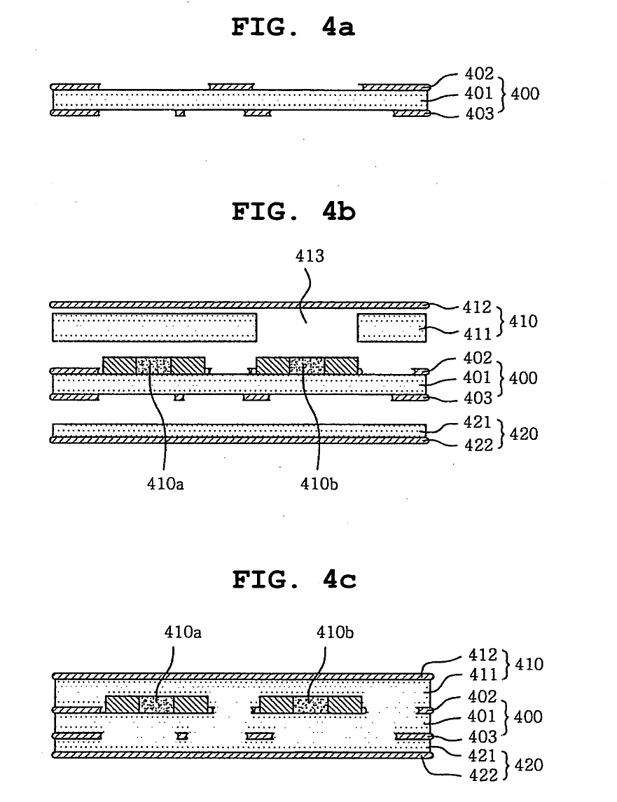

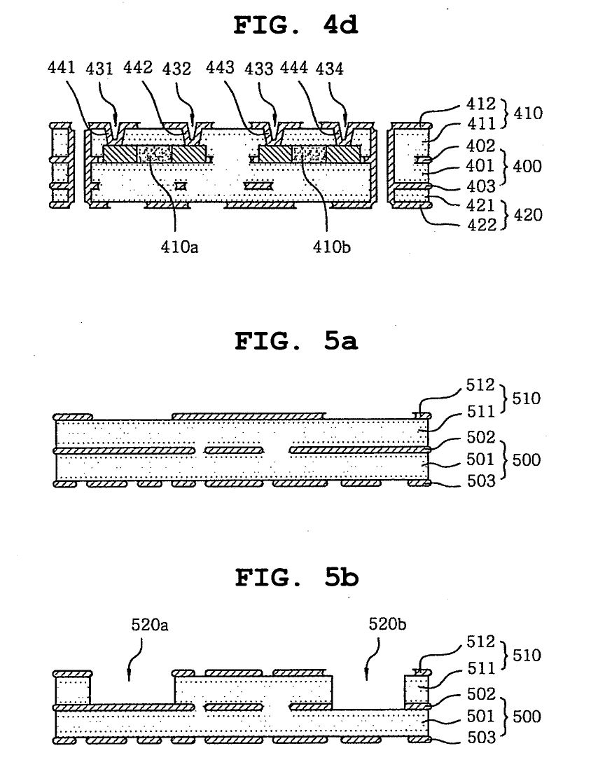

FIGS. 4a to 4d are sectional views illustrating the fabrication of a PCB including an embedded passive chip according to the fourth embodiment of the present invention.

The fourth embodiment as shown in FIGS. 4a to 4d is different from the third embodiment as shown in FIGS. 3a to 3d in that chips are mounted on a surface of a core layer in the fourth embodiment.

As shown in FIG. 4a, a copper clad laminate, consisting of an insulating resin layer 401 and copper foils 402, 403 coated on the insulating resin layer 401, is prepared as a substrate 400, and structures, in which passive chips 410a, 410b are to be mounted, are formed according to a photolithography process.

In this respect, it is preferable to simultaneously form circuits, to be formed on the copper foils 402, 403, and the structures, in which capacitor chips 410a, 410b are mounted.

Furthermore, as shown in FIG. 4b, the passive chips 41a, 410b are mounted in the structures, in which the passive chips 410a, 410b are to be mounted, and an insulator 411 or a substrate 410, which consists of the insulator 411 and a copper foil 412 formed on one side of the insulator 411, is laminated on the chips. At this time, it is preferable that holes 413 are formed through the insulator 411 so as to easily embed the passive chips 410a, 410b in the insulator 411, but the holes 413 may not be formed through the insulator 411.

Additionally, as shown in FIG. 4c, after the passive chips 410a, 410b are mounted in the structures, the insulator 411 or the substrate 410, which consists of the insulator 411 and the copper foil 412 formed on one side of the insulator 411, is coated on the chips, and heated and pressurized in a vacuum to embed the passive chips 410a, 410b in the insulator.

Successively, as shown in FIG. 4d, via holes 431-434 are formed, and walls of the via holes 431-434 are subjected to electroless copper plating and electrolytic copper plating processes to form copper clads 441-444 so as to connect electrodes of the passive chips 410a, 410b embedded in the PCB to each other through circuits. Additionally, after a coating of a dry film (not shown), the dry film is exposed and developed using an artwork film, having a predetermined pattern printed thereon, to be patterned. Furthermore, corrosive liquid is sprayed to remove the remaining portion of the copper foils except portions of the copper foils, which are protected by the dry film, and to strip the used dry film, thereby forming wiring patterns in the copper foils 412, 422.

As well, the passive chips, as shown in FIGS. 4a to 4d, may be mounted in two or more layers of insulator as well as in one layer of insulator.

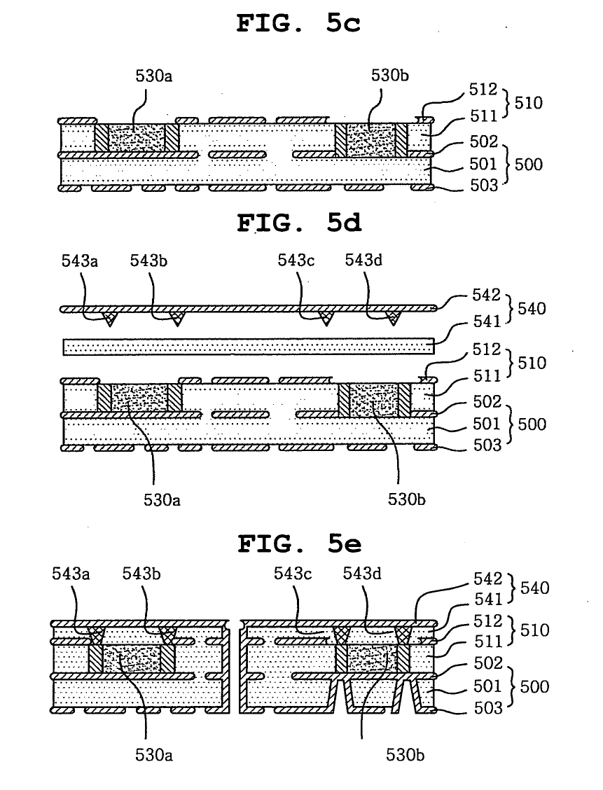

FIGS. 5a to 5e are sectional views illustrating the fabrication of a PCB including an embedded passive chip according to the fifth embodiment of the present invention.

As shown in FIG. 5a, circuit patterns are formed on copper foils 502, 503 of a substrate 500 constituting a core layer according to a photolithography process, and an insulator 511 or a substrate 510, which consists of the insulator 511 and a copper foil 512 formed on one side of the insulator 511, is laminated on the circuit pattern in a vacuum by heating and pressurization. Further, it is preferable to remove a portion of the copper foil 512 according to a photolithography process so as to form blind holes 520a, 520b, in which passive chips 530a, 530b are to be mounted.

Additionally, as shown in FIG. 5b, the blind holes 520a, 520b are formed in portions, in which passive chips 530a, 530b are to be mounted, and a circuit pattern is formed on the copper foil 512, through which the chips are to be inserted, according to a photolithography process. In this regard, corrosive liquid may be sprayed onto lower parts of the blind holes 520a, 520b for receiving the passive chips 530a, 530b to completely remove the lower parts, or the corrosive liquid may be prevented from flowing to the lower parts of the blind holes to allow the pattern of the copper foil 512, formed in the course of forming the circuit pattern, to remain.

Subsequently, as shown in FIG. 5c, the passive chips 530a, 530b are mounted in the blind holes 520a, 520b formed in portions, in which the passive chips 530a, 530b are to be mounted.

Successively, as shown in FIG. 5d, an insulator 541 or a substrate 540, which consists of the insulator 541 and a copper foil 542 formed on one side of the insulator 541, is laminated, and heated and pressurized in a vacuum, thereby embedding the passive chips 530a, 530b in the PCB. At this time, the copper foil 542 has bumps 543a-543d capable of being electrically connected to the passive chips 530a, 530b.

As well, as shown in FIG. 5e, a wiring pattern of the copper foil is formed according to a photolithography process.

Furthermore, the passive chips, as shown in FIGS. 5a to 5e, may be mounted in two or more layers of insulator as well as in one layer of insulator.

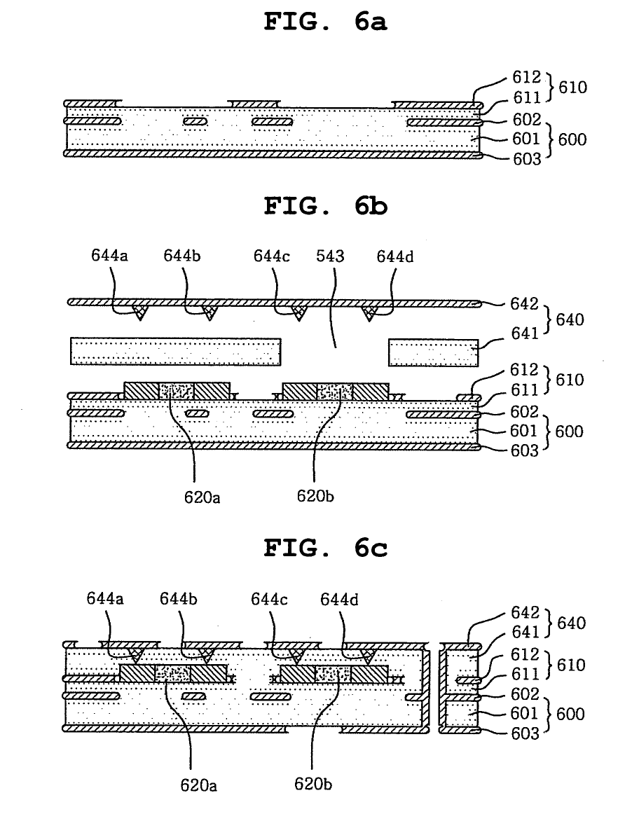

FIGS. 6a to 6c are sectional views illustrating the fabrication of a PCB including an embedded passive chip according to the sixth embodiment of the present invention.

As shown in FIG. 6a, circuit patterns are formed on copper foils 602, 603 of a substrate 600 according to a photolithography process, and an insulator 611 or a substrate 610, which consists of the insulator 611 and a copper foil 612 formed on one side of the insulator 611, is laminated on the circuit patterns in a vacuum by heating and pressurization. In this regard, it is preferable to remove a portion. of the copper foil 612, through which passive chips 620a, 620b are to be mounted, according to a photolithography process.

Subsequently, as shown in FIG. 6b, structures, in which the passive chips 620a, 620b are to be mounted, are formed according to a photolithography process, the passive chips 620a, 620b are mounted in the structures, and an insulator 641 or a substrate 640, which consists of the insulator 641 and a copper foil 642 formed on one side of the insulator 641, is laminated on the chips. At this time, it is preferable that the insulator 641 be holed so as to easily embed the passive chips 620a, 620b in the insulator 641, but holes may not be formed through the insulator 641. In this respect, the copper foil has bumps 644a-644d capable of being electrically connected to the passive chips 620a, 620b.

As well, as shown in FIG. 6c, wiring patterns of the copper foils 603, 642 are formed according to a photolithography process.

Furthermore, the passive chips, as shown in FIGS. 6a to 6c, may be mounted in two or more layers of insulator as well as in one layer of insulator.

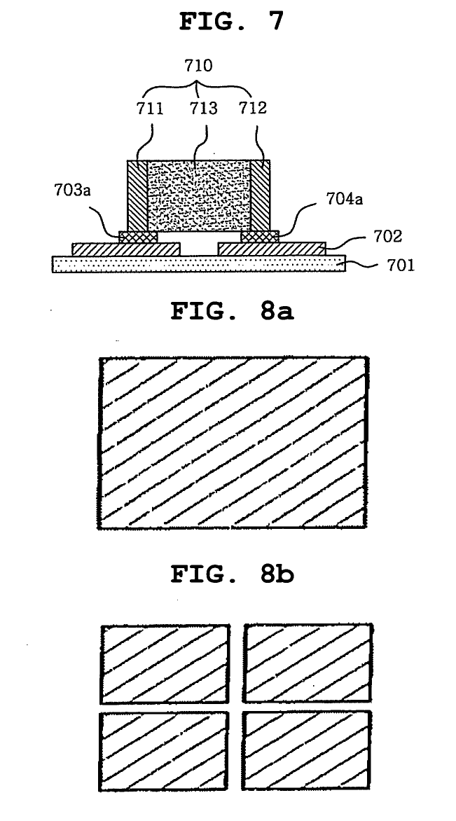

Meanwhile, as shown in FIG. 7, various shapes of patterns 702 may be formed under a passive chip 710. The patterns 702 function to reduce a thermal expansion coefficient difference between the passive chip and an insulator of a substrate, and may be connected through connection parts 703a, 704a to the chip. In this respect, when the connection parts each have electric conductivity, they electrically connect the patterns to the chip therethrough, and when the connection parts have no electric conductivity, they serve to bind the chip with pads.

The connection parts, that is, electrode expansion absorption patterns 703a, 704a function to absorb expansion of electrodes of the passive chip.

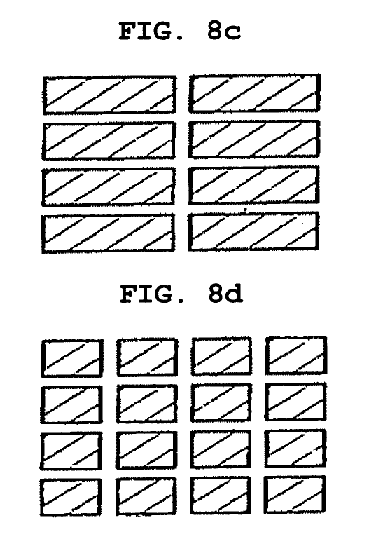

FIGS. 8a to 8d illustrate electrode expansion absorption patterns formed in the lower copper foils used in FIGS. 1a to 6c.

As shown in FIG. 8a, the electrode expansion absorption patterns may be formed in one structure in the lower copper foils.

As shown in FIGS. 8b to 8d, the electrode expansion absorption patterns may be formed in various shapes of pads or patterns.

Meanwhile, the passive chip may be any passive component capable of being mounted on a PCB.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

As described above, since parts, which are mounted on a surface of a substrate in a conventional SMT process, are embedded in the substrate in the present invention, a surface mounting area is increased, and thus, a size of the substrate is reduced, resulting in fabrication of more circuit boards in the same space than in the conventional SMT process.

Additionally, in the present invention, it is not necessary to form a solder joint unlike the conventional SMT process, and thus, use of lead, which must be regulated because it causes pollution, is reduced, and a signal noise is reduced.

Further, in the present invention, a passive component having a large capacitance, which is not realized in a conventional sheet type of PCB, can be embedded in a PCB, and thus, the present invention is useful in various applications.

Furthermore, in the present invention, a chip cannot fall through a PCB unlike a conventional chip embedding technology, thereby assuring ease of handling in the course of fabricating the PCB.

As well, in the present invention, since the chip is mounted in a blind hole instead of a through hole unlike conventional chip mounting technology, a circuit and various images can be formed on a lower part of the blind hole, on which the chip is mounted, that is, a copper foil for supporting the chip so as to prevent the chip from falling out of the blind hole, resulting in increased freedom in terms of design.

Furthermore, in the present invention, since a passive chip is not mounted in a core, but on a surface of the core or in an insulating resin layer, positioned on upper or lower sides of the core unlike conventional chip mounting technology, the distance between an active chip and the passive chip is reduced to reduce inductance, thereby improving electric performances.

In addition, in the present invention, a distance between passive and active components is reduced, and thus, a signal noise is reduced and high frequency characteristics are improved.

Furthermore, in the present invention, before a chip is mounted, an electric conductive material is applied to any one side of the contact parts of the chip, and it is electrically connected to the chip while being heated and pressurized or prior to be heated and pressurized, and thus, the number of holes formed for electric connection is reduced by a maximum of 50%.

Furthermore, a chip having a large capacitance, which is mounted in only a core layer in a conventional technology, is mounted in a space formed through multiple layers in the present invention, thereby making mounting of parts having a large volume possible.

Furthermore, in the present invention, a PCB can be electrically connected through a bump to a chip by employing only a heating and pressurizing process.

Furthermore, in the present invention, all parts, which are thin enough to be mounted and include resistors, as well as a passive chip, can be mounted in the PCB.

Furthermore, in the present invention, any passive component, capable of being mounted on a PCB, as well as a typical passive chip, having external electrodes at both longitudinal ends thereof, can be mounted in the PCB.

What is claimed is:

1. A method of fabricating a printed circuit board including an embedded passive chip, comprising:
a first step of forming a blind hole, in which the passive chip is to be mounted, in a first raw material layer laminated on a substrate constituting a core layer;
a second step of mounting the passive chip in the blind hole after a first circuit pattern is formed on a first copper foil of the first raw material layer, laminating an insulator or a second raw material layer, which consists of the insulator and a second copper foil formed on one side of the insulator, on the first raw material layer, in which the passive chip is mounted, and heating and pressurizing the resulting substrate;
a third step of forming a via hole electrically connecting an electrode of the passive chip to an external part therethrough; and
a fourth step of forming a copper clad on the via hole and a second circuit pattern on the external part.

2. The method as set forth in claim 1, further comprising a fifth step of removing a lower copper foil of the blind hole after the first step.

3. The method as set forth in claim 1, wherein when the first raw material layer is laminated on the core layer in the first step, a pad for electric connection and binding, which has a function of absorbing thermal expansion stress, is formed in a portion of a third copper foil of the core layer, on which the passive chip is mounted.

4. The method as set forth in claim 1, further comprising a fifth step of forming a pad for electric connection and binding, which has a function of absorbing thermal expansion stress, in a lower copper foil of the blind hole after the first step.

5. The method as set forth in claim 1, further comprising a fifth step of coating a conductive material on an area, in which the electrode of the passive chip is mounted, after the first step.

6. The method as set forth in claim 1, wherein the blind hole is formed through multiple layers of insulators.

7. The method as set forth in claim 1, wherein the passive chip is any passive component capable of being mounted on the printed circuit board.

8. A method of fabricating a printed circuit board including an embedded passive chip, comprising:
a first step of forming a blind hole, in which the passive chip is to be mounted, in a core layer in such a way that a portion of a first copper foil constitutes a bottom side of the blind hole, and forming a first circuit pattern on the first copper foil;
a second step of mounting the passive chip in the blind hole, laminating a first insulator or a first raw material layer, which consists of the first insulator and a second copper foil formed on one side of the first insulator, on the core layer, in which the passive chip is mounted, and heating and pressurizing the resulting core layer;
a third step of forming a second circuit pattern on the first copper foil constituting the bottom side of the blind hole, laminating a second insulator or a second raw material layer, which consists of the second insulator and a third copper foil formed on one side of the second insulator, on the first raw material layer, and heating and pressurizing the resulting second raw material layer;
a fourth step of forming a via hole electrically connecting an electrode of the passive chip to an external part; and
a fifth step of forming a copper clad on the via hole and a third circuit pattern on the external part.

9. The method as set forth in claim 8, further comprising a fifth step of removing a lower copper foil of the blind hole after the first step.

10. The method as set forth in claim 8, wherein when the first raw material layer is laminated on the core layer in the first step, a pad for electric connection and binding, which has a function of absorbing thermal expansion stress, is formed in a portion of a third copper foil of the core layer, on which the passive chip is mounted.

11. The method as set forth in claim 8, further comprising a fifth step of forming a pad for electric connection and binding, which has a function of absorbing thermal expansion stress, in a lower copper foil of the blind hole after the first step.

12. The method as set forth in claim 8, further comprising a fifth step of coating a conductive material on an area, in which the electrode of the passive chip is mounted, after the first step.

13. The method as set forth in claim 8, wherein the blind hole is formed through multiple layers of insulators.

14. The method as set forth in claim 8, wherein the passive chip is any passive component capable of being mounted on the printed circuit board.

15. A method of fabricating a printed circuit board including an embedded passive chip, comprising:
a first step of mounting the passive chip on a raw material layer laminated on a substrate constituting a core layer;
a second step of laminating an insulating resin layer on the raw material layer, on which the passive chip is mounted in the first step, and heating and pressurizing the resulting raw material layer;
a third step of forming a via hole electrically connecting an electrode of the passive chip to an external part therethrough; and
a fourth step of forming a copper clad on the via hole and a circuit pattern on the external part.

16. The method as set forth in claim 15, further comprising a fifth step of forming a hole, in which a capacitor chip is to be mounted, in the insulating resin layer laminated on the raw material layer, on which the passive chip is mounted, after the first step.

17. The method as set forth in claim 15, further comprising a fifth step of removing a portion of a copper foil, corresponding in position to the passive chip mounted on the raw material layer, from the raw material layer before the first step.

18. The method as set forth in claim 15, wherein a pad for electric connection and binding, which has a function of absorbing thermal expansion stress, is formed in a portion of a copper foil of the raw material layer, on which the passive chip is mounted, before the first step.

19. The method as set forth in claim 15, further comprising a fifth step of coating a conductive material on an area, in which the electrode of the passive chip is mounted, before the first step.

20. The method as set forth in claim 15, wherein the raw material layer laminated on the core layer has a multilayered structure, and the passive chip is mounted through multiple layers.

21. The method as set forth in claim 15, wherein the passive chip is any passive component capable of being mounted on the printed circuit board.

22. A method of fabricating a printed circuit board including an embedded passive chip, comprising:
a first step of mounting the passive chip on a core layer;
a second step of laminating an insulating resin layer on the core layer, on which the passive chip is mounted in the first step, and heating and pressurizing the resulting core layer;
a third step of forming a via hole electrically connecting an electrode of the passive chip to an external part therethrough; and
a fourth step of forming a copper clad on the via hole and a circuit pattern on the external part.

23. The method as set forth in claim 22, further comprising a fifth step of forming a hole, in which a capacitor chip is to be mounted, in the insulating resin layer laminated on the core layer, on which the passive chip is mounted, after the first step.

24. The method as set forth in claim 22, further comprising a fifth step of removing a portion of a copper foil, corresponding in position to the passive chip mounted on the core layer, from the core layer before the first step.

25. The method as set forth in claim 22, wherein a pad for electric connection and binding, which has a function of absorbing thermal expansion stress, is formed in a portion of a copper foil of the core layer, on which the passive chip is mounted, before the first step.

26. The method as set forth in claim 22, further comprising a fifth step of coating a conductive material on an area, in which the electrode of the passive chip is mounted, before the first step.

27. The method as set forth in claim 22, wherein a raw material layer laminated on the core layer has a multilayered structure, and the passive chip is mounted through multiple layers.

28. The method as set forth in claim 22, wherein the passive chip is any passive component capable of being mounted on the printed circuit board.

29. A method of fabricating a printed circuit board including an embedded passive chip, comprising:
a first step of forming a blind hole, in which the passive chip is to be mounted, in a first raw material layer laminated on a substrate constituting a core layer;
a second step of mounting the passive chip in the blind hole after a first circuit pattern is formed on a first copper foil of the first raw material layer;
a third step of laminating a second raw material layer, which includes a second copper foil having a conductive bump, on the first raw material layer, in which the passive chip is mounted, and heating and pressurizing the resulting structure; and
a fourth step of forming a second circuit pattern on an external part.

30. A method of fabricating a printed circuit board including an embedded passive chip, comprising:
a first step of mounting the passive chip on a first raw material layer laminated on a substrate constituting a core layer;
a second step of laminating a second raw material layer, which includes a copper foil having a conductive bump, on the first raw material layer, in which the passive chip is mounted, and heating and pressurizing the resulting structure; and
a third step of forming a circuit pattern on an external part.
